(19) United States
(12) Patent Application Publication
(10) Pub. No.: US 2022/0027712 A1
(43) Pub. Date: Jan. 27, 2022

(54) NEURAL MOSAIC LOGIC UNIT

(71) Applicant: National Technology & Engineering Solutions of Sandia, LLC, Albuquerque, NM (US)

(72) Inventor: James Bradley Aimone, Keller, TX (US)

(21) Appl. No.: 16/939,372

(22) Filed: Jul. 27, 2020

(51) Int. Cl. G06N 3/063; G11C 11/54; G11C 13/00

(52) U.S. Cl. CPC G06N 3/063; G11C 13/004; G11C 11/54

(57) ABSTRACT

A programmable logic unit is provided. The logic unit comprises a number of crossbar arrays. A control circuit connected to the crossbar arrays is configured to provide inputs to a specified subset of crossbar arrays according to a program. A layer of spiking neurons is connected to the crossbar arrays, wherein respective outputs from the crossbar arrays are summed together and input into the spiking neurons. A temporal buffer circuit is configured to hold spiking activation signals from the spiking neurons for a delay time specified by the program before routing the spiking activation signals back to the crossbar arrays as input through the control circuit.

### STATEMENT OF GOVERNMENT INTEREST

This invention was made with United States Government support under Contract No. DE-NA0003525 between National Technology & Engineering Solutions of Sandia, LLC and the United States Department of Energy. The United States Government has certain rights in this invention.

### BACKGROUND

### 1. Field

The disclosure relates generally to programmable logic units, and more specifically to a logic unit comprising a mosaic of stacked crossbar arrays for neural network computations.

### 2. Description of the Related Art

Resistive memory crossbars have been shown to be effective at performing efficient analog vector matrix operations that underpin many of the relevant computations in neural computations. By applying Kirchoff s Law integration to sum currents across a number of voltage resistor pairs, crossbars can perform highly efficient analog computation, albeit with some limitations in precision and tuning. Precision limitations can be offset by operating with higher voltages. However, the higher voltages offset the energy advantages of the analog computation. As much of the focus on neural computation has been on artificial neural networks, most crossbars have been limited by the need to use dense inputs (all input channels on at a certain level) and dynamic tuning of the resistive memory weights.

Therefore, it would be desirable to have a method and apparatus that take into account at least some of the issues discussed above, as well as other possible issues.

### SUMMARY

An illustrative embodiment provides a programmable logic unit. The logic unit comprises a number of crossbar arrays. A control circuit connected to the crossbar arrays is configured to provide inputs to a specified subset of crossbar arrays according to a program. A layer of spiking neurons is connected to the crossbar arrays, wherein respective outputs from the crossbar arrays are summed together and input into the spiking neurons. A temporal buffer circuit is configured to hold spiking activation signals from the spiking neurons for a delay time specified by the program before routing the spiking activation signals back to the crossbar arrays as input through the control circuit.

Another illustrative embodiment provides system comprising two or more programmable logic units. Each logic unit comprises a number of crossbar arrays. A control circuit connected to the crossbar arrays is configured to provide inputs to a specified subset of crossbar arrays according to a program. A layer of spiking neurons is connected to the crossbar arrays, wherein respective outputs from the crossbar arrays are summed together and input into the spiking neurons. A temporal buffer circuit is configured to hold spiking activation signals from the spiking neurons for a delay time specified by the program before routing the spiking activation signals back to the crossbar arrays as input through the control circuit. Each logic unit also comprises a communication substrate configured to send spiking activation signals from the temporal buffer circuit to other programmable logic units in the system and input spiking activation signals from other programmable logic units in the system into the temporal buffer circuit.

Another illustrative embodiment provides a method of computing with a programmable logic unit. The method comprises receiving, by a control circuit, program instructions and input data and inputting signals from the control circuit to a specified subset of crossbar arrays within a number of crossbar arrays according to the program instructions. The respective outputs from the subset of crossbar arrays are summed and input into a layer of spiking neurons. Spiking activation signals are output from the spiking neurons to a temporal buffer in response to the summed outputs. The spiking activation signals are held in the temporal buffer for a delay specified by the program and then input back to the crossbar arrays through the control circuit after the specified delay.

The features and functions can be achieved independently in various examples of the present disclosure or may be combined in yet other examples in which further details can be seen with reference to the following description and drawings.

### BRIEF DESCRIPTION OF THE DRAWINGS

The novel features believed characteristic of the illustrative embodiments are set forth in the appended claims. The illustrative embodiments, however, as well as a preferred mode of use, further objectives and features thereof, will best be understood by reference to the following detailed description of an illustrative embodiment of the present disclosure when read in conjunction with the accompanying drawings, wherein:

FIG. 1 depicts a block diagram illustrating a programmable Neural Mosaic Logic Unit in accordance with an illustrative embodiment;

FIG. 2 depicts a resistive crossbar with which the illustrative embodiments can be implemented;

FIG. 3 depicts a mosaic crossbar stack and spiking neural circuit in accordance with an illustrative embodiment;

FIG. 4 is a diagram that illustrates a node in a neural network with which illustrative embodiments can be implemented;

FIG. 5 is a diagram illustrating a neural network in which illustrative embodiments can be implemented;

FIG. 6 illustrates the selective activation of crossbars by the control circuit in accordance with an illustrative embodiment;

FIG. 7 depicts a multi-NMLU architecture in accordance with an illustrative embodiment; and

FIG. 8 depicts a flowchart illustrating a process of computing with a NMLU in accordance with an illustrative embodiment.

### DETAILED DESCRIPTION

The illustrative embodiments recognize and take into account one or more different considerations. For example, the illustrative embodiments recognize and take into account that spiking neural algorithms (SNAs) are crafted neural circuits which leverage spiking, or event-based communication, to achieve potential power advantages and neural circuit formulation to provide a powerful logic substrate to enable computation. However, the value of SNAs is best realized with a suitable hardware substrate. There is a growing library of SNAs that can represent known arithmetic functions exactly (e.g., matrix multiplication, Fourier decomposition, cross-correlations, sort, max, min, etc.), and it is expected that most arithmetic operations can be represented as SNAs.

The illustrative embodiments also recognize and take into account that resistive memory crossbars (xBars) have been shown to be effective at performing efficient analog vector matrix operations that underpin many of the relevant computations in neural computation. By applying Kirchoff s Law integration to sum currents across a number of voltage resistor pairs, crossbars can perform highly efficient analog computation, albeit with some limitations in precision and tuning. Precision limitations can be offset by operating with higher voltages. However, this higher voltage offsets the energy advantages of the analog computation. As much of the focus on neural computation has been on artificial neural networks, most crossbars have been limited by the need to use dense inputs (all input channels on at a certain level) and dynamic tuning of the resistive memory weights.

The illustrative embodiments provide a Neural Mosaic Logic Unit (NMLU) architecture that the above concerns by pre-allocating circuits to perform key kernels of SNAs and allowing these kernels to be subsequently fixed indefinitely. The NMLU is a novel computer architecture providing a readily programmable low-power neural substrate at high-density. The NMLU leverages three emerging technologies: (1) spike-based neural algorithms for desired precision operations; (2) crossbar memory technology, that can be suitable for 3D integration when operated in a low-power manner; and (3) the mosaic concept for dynamically allocating synaptic memory to a finite number of neuron processors. The NMLU concept is configurable and modular. A computing system may achieve advantageous operation using a single NMLU for a programmed function, or it may use many NMLUs in parallel with a higher-level communication interface to couple several NMLUs.

Since SNAs are spiking, the NMLU neither requires high precision voltages (i.e., lower voltages are suitable) nor are all channels active at once. As explained in detail below, in operation the NMLU requires only a fraction of the crossbar SNA kernels to be used at a given time-step of a program, thereby enabling most of the crossbars to sit “off.” This feature enables a 3D stacking of the crossbar SNA kernels.

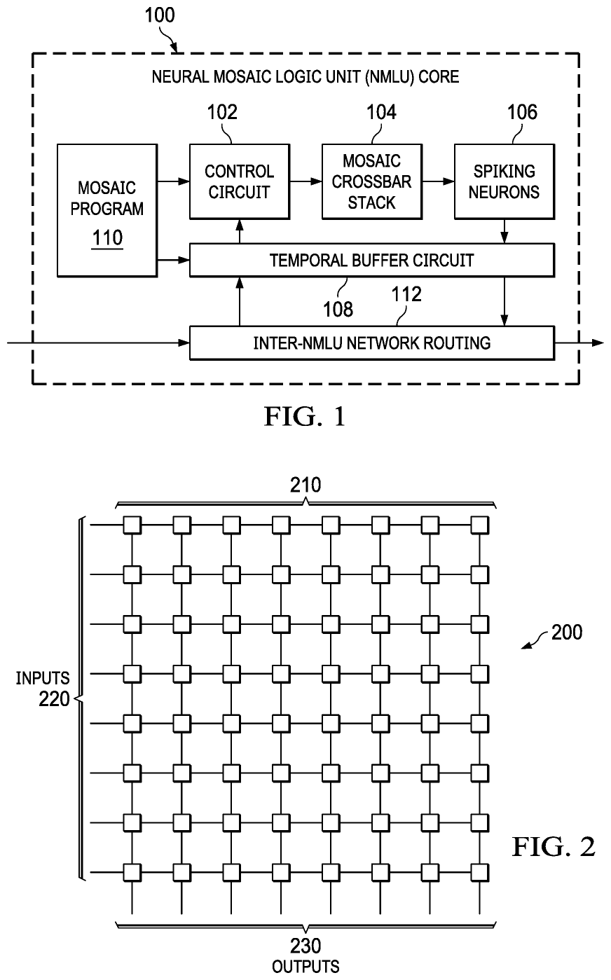

FIG. 1 depicts a block diagram illustrating a programmable NMLU in accordance with an illustrative embodiment. The NMLU core 100 comprises control circuit 102, mosaic crossbar stack 104, spiking neurons 106, temporal buffer circuit 108, mosaic program 110, and inter-NMLU network routing substrate 112.

Mosaic crossbar stack 104 comprises a dense crossbar architecture. In an embodiment, the crossbars are stacked as layers in a three-dimensional architecture. Alternatively, the crossbars can be arranged in a two-dimensional layout. The crossbars in crossbar mosaic 104 share a set of spiking neurons 106. Spiking neurons 106 produce spiking activation signals in response to summed outputs from the mosaic stack 104.

Control circuit 102 comprises a programmable substrate that provides program instructions and input data from mosaic program 110 to crossbar mosaic 104 and controls which crossbars are active for a given time-step of program 110.

Temporal buffer circuit 108 comprises a streaming circuit that holds spiking activation signals from spiking neurons 106 for a delay time specified by program 110. After the specified delay, the spiking activation signals are then fed by the temporal buffer circuit 108 back into the mosaic stack 104 through control circuit 102 to serve as inputs for another time-step of mosaic program 110.

Both the actual program 110 (the sequence of mosaic steps and relevant delays) and the initial input data (e.g., source dataset for computations, graph, etc.) are input into the NMLU system through an I/O system (not shown).

In an embodiment in which NMLU 100 is used in conjunction with other NMLUs, inter-NMLU network routing 112 provides a communication substrate to link NMLU 100 to the other NMLUs. Temporal buffer circuit 108 can receive and send spiking activation signals from and other NMLUs through inter-NMLU network routing 112.

FIG. 2 depicts a resistive crossbar with which the illustrative embodiments can be implemented. Crossbar arrays enable the area-efficient integration of many devices that can be connected to vertical and horizontal wires. As shown in FIG. 2, crossbar array 200 comprises memristors 210, input lines 220, and output lines 230. Crossbar array 200 incorporates memristors 210 at each row/column intersection in the array. Each memristor element 210 at each row/column intersection within the crossbar array 200 can have a distinct specified conductance.

The N×M crossbar array 200 comprises N horizontal input wires (word lines) 220 and M vertical output wires (bit lines) 230. Memristors 210 are placed at the intersections between the word and bit lines. The individual states of the memristors 210 determine the electrical connectivity between the various input lines 220 and output lines 230, and therefore the amount of current transmitted from the input lines 220 to the output lines 230. Though FIG. 2 shows an 8×8 crossbar, it should be noted that the size of a crossbar array can be varied and that the structure need not be square.

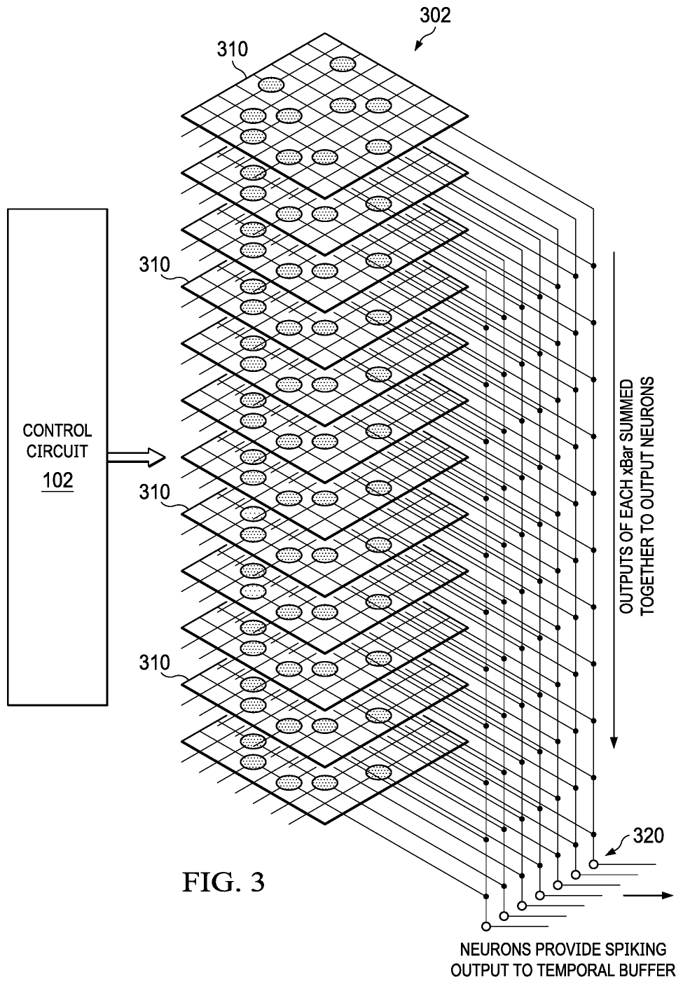

FIG. 3 depicts a mosaic crossbar stack and spiking neural circuit in accordance with an illustrative embodiment. FIG. 3 illustrates a detailed example of mosaic crossbar 104 and spiking neurons 106 in FIG. 1.

In the example shown, mosaic stack 302 comprises a number of resistive crossbar arrays 310 that are stacked in a 3D configuration. Each crossbar array 310 represents a different computation performed on data input into the stack 302 by the control circuit 102. Neural algorithms (either SNAs or artificial neural networks (ANNs)) can be decomposed into sequences of constituent subnetworks, referred to as mosaics. In the illustrative embodiments, the mosaics are treated as individual crossbars 310 representing SNA subnetworks. The mosaics can be sequentially computed to represent the larger SNA with moderate leveraging of delays (provided by temporal buffer 108) to synchronize the overall operation.

The inputs are provided as voltage increases to the crossbar arrays 310. As explained above, each row/column intersection within the crossbar arrays 310 can have a distinct conductance that transforms the input voltage into an output current. These output currents from the crossbars are summed together according to Kirchoff's Law. The summed output currents are accordingly fed through a population of hardware instantiated spiking neurons 320 shared by all crossbars 310 in the mosaic stack 302.

The output of neurons 320 is a spiking activation, which is fed into the temporal buffer 108. The timing of when those activations leave the temporal buffer 108 is a function of the mosaic program 110. The temporal buffer assigns and retrieves spiking activations according to the original program.

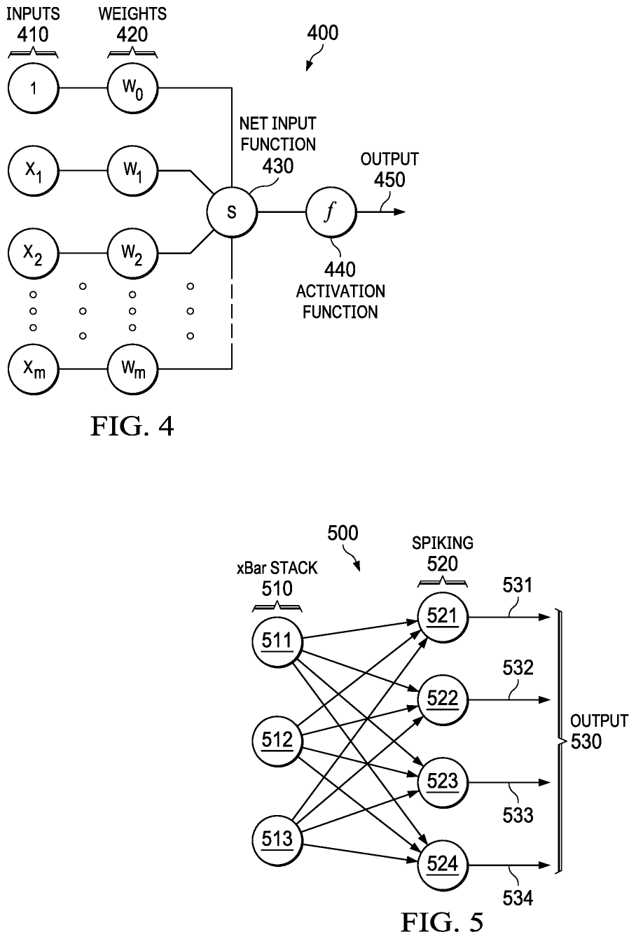

FIG. 4 is a diagram that illustrates a node in a neural network with which illustrative embodiments can be implemented. Node 400 might be an example of a node in spiking output nodes 106 and 320 shown in FIGS. 1 and 3, respectively. Node 400 combines multiple inputs 410. Each input 410 is multiplied by a respective weight 420 that either amplifies or dampens that input, thereby assigning significance to each input for the task the algorithm is trying to learn. The weighted inputs are collected by a net input function 430 and then passed through an activation function 440 to determine the output 450. The connections between nodes are called edges. The respective weights of nodes and edges might change as learning proceeds, increasing or decreasing the weight of the respective signals at an edge. A node might only send a signal if the aggregate input signal exceeds a predefined threshold. Pairing adjustable weights with input features is how significance is assigned to those features with regard to how the network classifies and clusters input data.

Neural networks are often aggregated into layers, with different layers performing different kinds of transformations on their respective inputs. A node layer is a row of nodes that turn on or off as input is fed through the network. Signals travel from the first (input) layer to the last (output) layer, passing through any layers in between. Each layer's output acts as the next layer's input.

FIG. 5 is a diagram illustrating a neural network in which illustrative embodiments can be implemented. As shown in FIG. 5, the nodes in the neural network 500 are divided into a layer of input nodes 510 and a layer of output nodes 520. For ease of illustration, input nodes 510 might represent crossbar stack 302 in FIG. 3. The input nodes 510 are those that receive information from the environment (i.e. input data from mosaic program 110 via control circuit 102). Each node in layer 510 takes a low-level feature from an item in the input dataset and passes it to the output nodes in layer 520, which might be examples of spiking neurons 106, 320. When a node in layer 520 receives an input value x from a node in layer 510 it multiplies x by the weight assigned to that connection (edge) and adds it to a bias b. The result of these two operations is then fed into an activation function which produces the node's output.

Spiking neural networks (SNN) incorporate the concept of time into their operating model. One of the most important differences between SNNs and other types of neural networks is the way information propagates between units/nodes.

Whereas other types of neural networks communicate using continuous activation values, communication in SNNs is done by broadcasting trains of action potentials, known as spike trains. In biological systems, a spike is generated when the sum of changes in a neuron's membrane potential resulting from pre-synaptic stimulation crosses a threshold. This principle is simulated in artificial SNNs in the form of a signal accumulator that fires when a certain type of input surpasses a threshold. The intermittent occurrence of spikes gives SNNs the advantage of much lower energy consumption than other types of neural networks. A synapse can be either excitatory (i.e. increases membrane potential) or inhibitory (i.e. decreases membrane potential). The strength of the synapses (weights) can be changed as a result of learning.

Information in SNNs is conveyed by spike timing, including latencies and spike rates. SNNs allow learning (weight modification) that depends on the relative timing of spikes between pairs of directly connected nodes. Under the learning rule known as spike-timing-dependent plasticity (STDP) the weight connecting pre- and post-synaptic units is adjusted according to their relative spike times within a specified time interval. If a pre-synaptic unit fires before the post-synaptic unit within the specified time interval, the weight connecting them is increased (long-term potentiation (LTP)). If it fires after the post-synaptic unit within the time interval, the weight is decreased (long-term depression (LTD)).

The leaky integrate-and-fire (LIF) neuron has been a primary area of interest for the development of an artificial neuron and is a modified version of the original integrate-and-fire circuit. The LIF neuron is based on the biological neuron, which exhibits the following functionalities:

1) Integration: Accumulation of a series of input spikes,

2) Leaking: Leaking of the accumulated signal over time when no input is provided, and

3) Firing: Emission of an output spike when the accumulated signal reaches a certain level after a series of integration and leaking.

An LIF neuron continually integrates the energy provided by inputs until a threshold is reached and the neuron fires as a spike that provides input to other neurons via synapse connections. By emitting this spike, the neuron is returned to a low energy state and continues to integrate input current until its next firing. Throughout this process, the energy stored in the neuron continually leaks. If insufficient input is provided within a specified time frame, the neuron gradually reverts to a low energy state. This prevents the neuron from indefinitely retaining energy, which would not match the behavior of biological neurons.

In fully connected feed-forward networks, each node in one layer is connected to every node in the next layer. For example, node 521 receives input from all of the nodes 511-513 each x value from the separate nodes is multiplied by its respective weight, and all of the products are summed. The summed products are then added to the bias of layer 520, and the result is passed through the activation function to produce output 531. A similar process is repeated at nodes 522-524 to produce respective outputs 532-534.

In the case of a NMLU, the spiking activation outputs 530 of layer 520 are held in temporal buffer circuit 108 to serve as inputs to the crossbar stack 104, 302 at a later time-step of mosaic program 110.

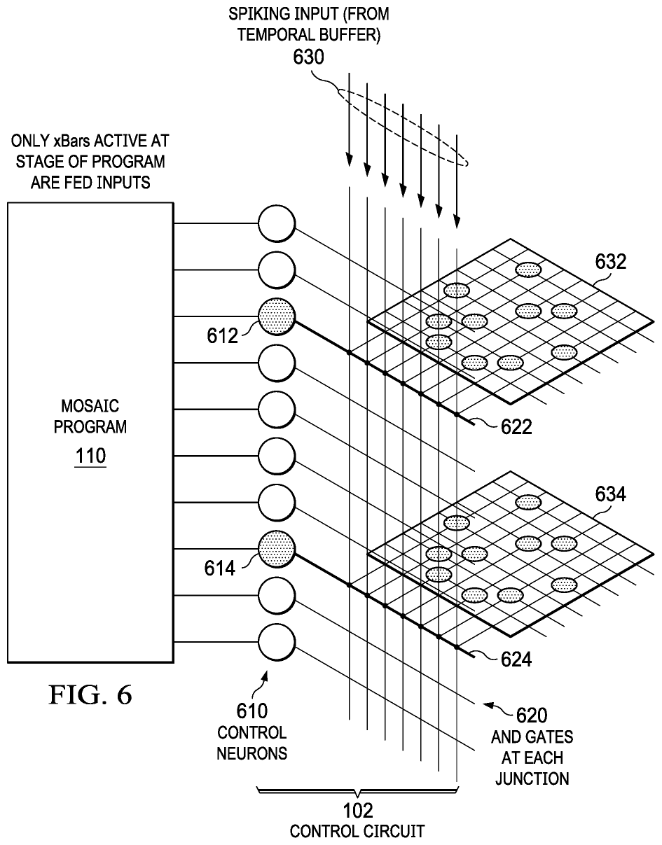

FIG. 6 illustrates the selective activation of crossbars by the control circuit in accordance with an illustrative embodiment. If the neural models are generic, such as a basic LIF model, the subnetworks can operate sequentially on a common architecture and yield the desired result. In the illustrative embodiments, the operation of the SNA proceeds by the relevant subnetworks' crossbars being progressively activated according to the mosaic instructions in program 110. At a given time-step in program 110, only a subset of crossbars within the mosaic stack need to be active. The mosaic program 110 input by the user at run-time dictates to the control circuit the relevant subset of crossbars to activate at that timestep.

As shown in FIG. 6, control circuit 102 comprises a number of control neurons/nodes 610 that are connected to crossbars in the mosaic stack by AND gates 620 at each junction between the stack and control circuit. In the illustrated example, control neurons 612 and 614 in the control circuit 102 provide the timestep's spiking inputs 630 (from the temporal buffer) to selected crossbars 632 and 634 through respective AND gates 622 and 624. (or potentially another type of select device). The respective outputs of crossbars 632 and 634 are summed and input into the spiking neurons 320 as shown in FIG. 3.

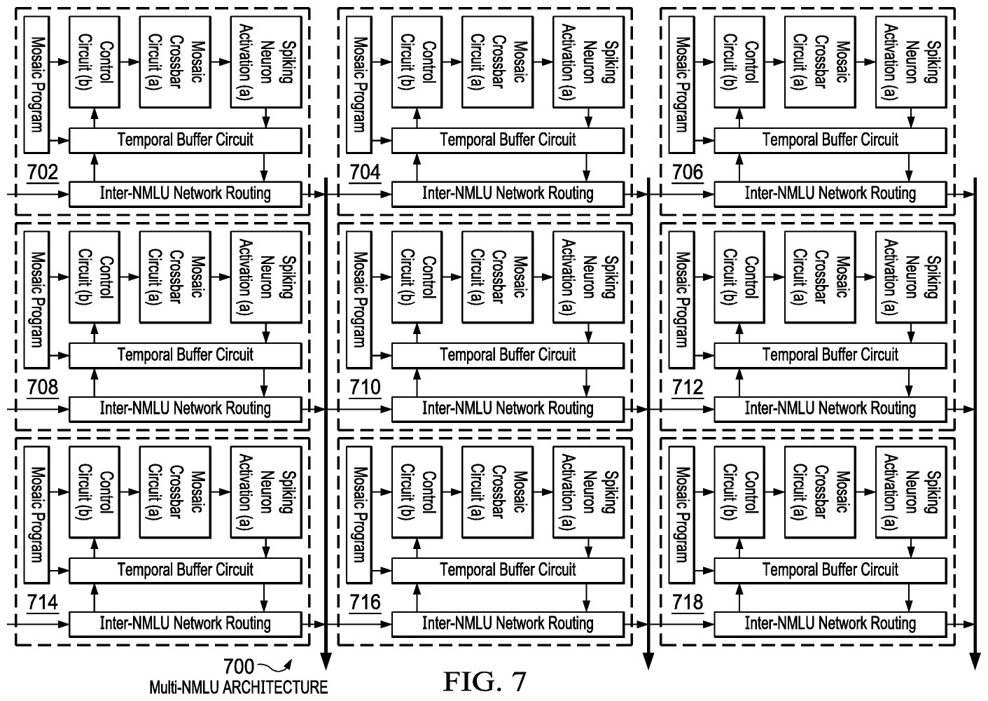

FIG. 7 depicts a multi-NMLU architecture in accordance with an illustrative embodiment. Architecture 700 illustrates the scalability of the NMLU configuration 100 shown in FIG. 1, allowing mosaic programs to operate entirely in parallel or in a more distributed mode, with elements of the computation shared across multiple NMLU cores, e.g., NMULUs 702-718. This integrated parallel operation of NMLUs requires spiking outputs to be shared between NMLUs through a routing network, with transferred spiking activations deposited in the relevant location of the temporal buffer in the receiving NMLU.

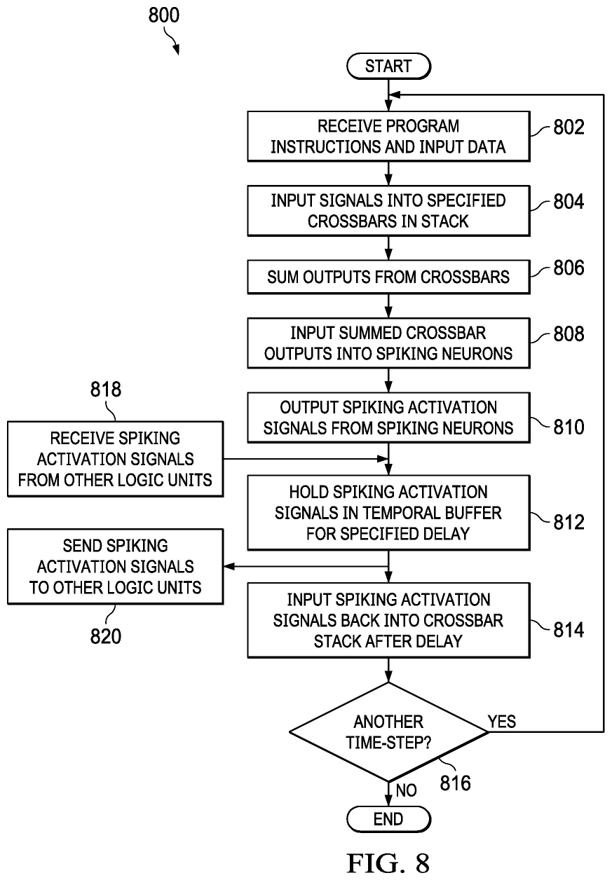

FIG. 8 depicts a flowchart illustrating a process of computing with a NMLU in accordance with an illustrative embodiment. Process 800 might be carried out with the NMLU structures depicted in FIGS. 1-7 and illustrates a single time-step in a mosaic program.

Process 800 begins by the control circuit receiving program instructions and input data (step 802). The control circuit inputs signals to a specified subset of crossbar arrays within the stack according to the program instructions (step 804). The control circuit provides input to the specified crossbar arrays through AND gates at junctions connecting each crossbar array to the control circuit. The specified subset of crossbars comprise only crossbar arrays that are designated as active at the specific time-step of the program.

The outputs of the active subset of crossbar arrays are summed as a property of Kirchoff's Law (step 806) and input into a layer of spiking neurons (step 808). The spiking neurons output spiking activation signals to a temporal buffer circuit in response to the summed outputs (step 810).

Optionally, if the NMLU is part of a multi-NMLU architecture, the temporal buffer circuit might also receive spiking activation signals from other NMLUs (step 818).

The temporal buffer circuit holds the spiking activation signals for a delay time specified by the program (step 812). After the specified delay, the temporal buffer inputs the spiking activation signals back into the mosaic crossbar stack through the control circuit to another subset of crossbar arrays according to the program (step 814). Optionally, if the NMLU is part of a multi-NMLU architecture, the temporal buffer circuit might also send the spiking activation signals to other NMLUs (step 820).

Process 800 then determines if there is another time-step in the program (step 816). If there is another time-step, process 800 returns to step 802. If there are no more time-steps in the program, process 800 ends.

The NMLU of the illustrative embodiments combines the advantageous aspects of the mosaic approach to distributing a large neural algorithm over a finite number of neurons (neurons are more expensive in terms of storage and size than connections) with the low-power benefits of spiking communication and the low-power, high speed, and density benefits of the crossbar memory architecture.

In an embodiment, the crossbars are configurable at run time, not unlike an field programmable analog array (FPAA) or field programmable gate array FPGA. This embodiment requires external access to each crossbar of each NMLU mosaic stack, with training circuitry available to tailor the relevant crossbar to the desired function.

In another embodiment, the tuning operation is performed once, wherein the relevant crossbar functionality is permanently flashed onto the non-volatile crossbar elements at the start. Different programs can subsequently perform different overall series of operations, but the individual neural functions are fixed.

In an embodiment, fabrication of the NMLU might comprise resistive memory analog devices (e.g., memristors) as part of the crossbar mosaic stack that would enable high-density 3D integration. The neuron devices could be either analog or CMOS. The control circuitry might comprise digital CMOS. Alternatively, the NMLU can be constructed entirely from silicon CMOS using conventional techniques, with the crossbar elements represented by SRAM in a 2D tiled, rather than stacked, configuration.

As used herein, the phrase “a number” means one or more. The phrase “at least one of”, when used with a list of items, means different combinations of one or more of the listed items may be used, and only one of each item in the list may be needed. In other words, “at least one of” means any combination of items and number of items may be used from the list, but not all of the items in the list are required. The item may be a particular object, a thing, or a category.

For example, without limitation, “at least one of item A, item B, or item C” may include item A, item A and item B, or item C. This example also may include item A, item B, and item C or item B and item C. Of course, any combinations of these items may be present. In some illustrative examples, “at least one of” may be, for example, without limitation, two of item A; one of item B; and ten of item C; four of item B and seven of item C; or other suitable combinations.

The flowcharts and block diagrams in the different depicted embodiments illustrate the architecture, functionality, and operation of some possible implementations of apparatuses and methods in an illustrative embodiment. In this regard, each block in the flowcharts or block diagrams may represent at least one of a module, a segment, a function, or a portion of an operation or step. For example, one or more of the blocks may be implemented as program code.

In some alternative implementations of an illustrative embodiment, the function or functions noted in the blocks may occur out of the order noted in the figures. For example, in some cases, two blocks shown in succession may be performed substantially concurrently, or the blocks may sometimes be performed in the reverse order, depending upon the functionality involved. Also, other blocks may be added in addition to the illustrated blocks in a flowchart or block diagram.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiment. The terminology used herein was chosen to best explain the principles of the embodiment, the practical application or technical improvement over technologies found in the marketplace, or to enable others of ordinary skill in the art to understand the embodiments disclosed here.

What is claimed is:

1. A programmable logic unit, comprising:
a number of crossbar arrays;
a control circuit connected to the crossbar arrays and configured to provide inputs to a specified subset of crossbar arrays according to a program;
a layer of spiking neurons connected to the crossbar arrays, wherein respective outputs from the crossbar arrays are summed together and input into the spiking neurons; and
a temporal buffer circuit configured to hold spiking activation signals from the spiking neurons for a delay time specified by the program before routing the spiking activation signals back to the crossbar arrays as input through the control circuit.

2. The logic unit of claim 1, wherein each crossbar array represents a different computation.

3. The logic unit of claim 1, wherein the control circuit provides input to the specified subset of crossbar arrays through AND gates at junctions connecting each crossbar array to the control circuit.

4. The logic unit of claim 3, wherein the specified subset of crossbar arrays comprises only crossbar arrays that are designated as active at a given step of the program.

5. The logic unit of claim 1, wherein inputs are provided as voltage increases to the crossbar arrays, wherein each row/column intersection in each crossbar array has a specified conductance that transforms the input voltage into an output current.

6. The logic unit of claim 1, wherein the control circuit provides inputs to different crossbar arrays in a sequence that is specific to the program.

7. The logic unit of claim 1, wherein each crossbar array represents a subnetwork within a spiking neural algorithm.

8. The logic unit of claim 1, further comprising a circuit configured to load program instructions and input data into the control circuit.

9. The logic unit of claim 1, further comprising a communication substrate configured to:
send spiking activation signals from the temporal buffer circuit to other programmable logic units; and
input spiking activation signals from other programmable logic units into the temporal buffer circuit.

10. The logic unit of claim 1, wherein the crossbar arrays are arranged in a stack.

11. The logic unit of claim 1, wherein the crossbar arrays are arranged in a tile configuration.

12. A system, comprising:
two or more programmable logic units, each logic unit comprising:
a number of crossbar arrays;
a control circuit connected to the crossbar arrays and configured to provide inputs to a specified subset of crossbar arrays according to a program;
a layer of spiking neurons connected to the crossbar arrays, wherein respective outputs from the crossbar arrays are summed together and input into the spiking neurons;
a temporal buffer circuit configured to hold spiking activation signals from the spiking neurons for a delay time specified by the program before routing the spiking activation signals back to the crossbar arrays as input through the control circuit; and
a communication substrate configured to:
send spiking activation signals from the temporal buffer circuit to other programmable logic units in the system; and
input spiking activation signals from other programmable logic units in the system into the temporal buffer circuit.

13. The system of claim 12, wherein each crossbar array represents a different computation.

14. The system of claim 12, wherein the crossbar arrays in each logic unit are arranged in a stack.

15. The system of claim 12, wherein the control circuit in each logic unit provides input to the specified subset of crossbar arrays through AND gates at junctions connecting each crossbar array to the control circuit.

16. The system of claim 12, wherein inputs are provided as voltage increases to the crossbar arrays, wherein each row/column intersection in each crossbar array has a specified conductance that transforms the input voltage into an output current.

17. A method of computing with a programmable logic unit, the method comprising:
receiving, by a control circuit, program instructions and input data;
inputting signals from the control circuit to a specified subset of crossbar arrays within a number of crossbar arrays according to the program instructions;
summing respective outputs from the subset of crossbar arrays;
inputting the summed outputs into a layer of spiking neurons;
outputting spiking activation signals from the spiking neurons to a temporal buffer in response to the summed outputs;
holding the spiking activation signals in the temporal buffer for a delay specified by the program; and
inputting the spiking activation signals back to the crossbar arrays through the control circuit after the specified delay.

18. The method of claim 17, wherein each crossbar array represents a different computation.

19. The method of claim 17, wherein the specified subset of crossbar arrays comprises only crossbar arrays that are designated as active at a given step of the program.

20. The method of claim 17, wherein the control circuit provides inputs to different crossbar arrays in a sequence that is specific to the program.

21. The method of claim 17, wherein each crossbar array represents a subnetwork within a spiking neural algorithm.

22. The method of claim 17, further comprising sending spiking activation signals from the temporal buffer circuit to other programmable logic units.

23. The method of claim 17, further comprising receiving spiking activation signals from other programmable logic units into the temporal buffer circuit.
